(19) United States
(12) Patent Application Publication
(10) Pub. No.: US 2026/0057143 A1
(43) Pub. Date: Feb. 26, 2026

(54) AUTOENCODER-BASED MACHINE-LEARNED INTERATOMIC POTENTIALS FOR SCALABLE, AUGMENTED HAMILTONIANS

(71) Applicant: Robert Bosch GmbH, Stuttgart (DE)

(72) Inventors: Mordechai KORNBLUTH, Brighton, MA (US); Daniil KITCHAEV, Brookline, MA (US); Nicola MOLINARI, Cambridge, MA (US); Karim GADELRAB, Boston, MA (US)

(21) Appl. No.: 18/813,807

(22) Filed: Aug. 23, 2024

(51) Int. Cl. G06F 30/25; G06N 3/0455; G06N 3/084

(52) U.S. Cl. CPC G06F 30/25; G06N 3/0455; G06N 3/084

(57) ABSTRACT

Methods for a machine learning network that train and subsequently execute both an autoencoder and a machine learning model within a context of machine-learning interatomic potentials are disclosed. The system described herein is configured to embed atomic positions and species of a given atomic system and apply those to an autoencoder in order to learn an auxiliary property and to a machine learning model in order to learn local energies. The auxiliary property is then used to generate an auxiliary Hamiltonian description. By combining both the auxiliary Hamiltonian description and the local energies, properties such as total energy of the atomic system are determined. By processing the machine learning through both an autoencoder and a machine learning model, such methods ensure that long and short range effects are accounted for, while also appropriately enabling for realistic discontinuities and/or transitions within the potential energy surface.

### TECHNICAL FIELD

The present disclosure relates to training and executing a combination of an autoencoder and machine learning model in order to determine long and short range energies of a given atomic system.

### BACKGROUND

Various machine learning techniques have proven useful within a context of predicting interaction energies, forces, and other properties of various atomic systems. However, there is a non-trivial balancing of the usage of a given machine learning model for large-scale atomic systems while also taking into account short-range effects and transitions (e.g., a magnetic transition). Providing scalable machine learning techniques for implementation into iterative processes, such as molecular dynamics, remains a challenge.

### SUMMARY

In contrast to previous implementations of machine-learning interatomic potentials (MLIPs), the present disclosure utilizes both an autoencoder and a machine learning model to determine properties of an atomic system, such as the total energy in the system. The autoencoder ensures that the particular MLIP architecture is scalable, and can be implemented into larger-scale simulations, such as molecular dynamics, and with accuracy similar to that of ab-initio methods. The combination of accuracy and scalability is due, at least in part, to restricting the latent space of the autoencoder, such that the autoencoder has a fixed dimension. The output, therefore, is a set of discretized states. Those discretized states may then be used to determine an auxiliary Hamiltonian description of a given atomic system which can be efficiently scaled to large systems. When combined with local energies that are learned using a deep neural network, one or more Gaussian processes, or some other type of MLIP-based model, the resulting total energy accounts for both large-scale and short-scale effects within the system, and appropriately allows for discontinuities and/or transitions, when relevant to the particular atomic system and simulation environment.

### BRIEF DESCRIPTION OF THE DRAWINGS

FIG. 1 illustrates a system for training and utilizing a machine learning model, such as a neural network, according to some embodiments.

FIG. 2 illustrates a computer-implemented method for training and utilizing a machine learning model, such as a neural network, according to some embodiments.

FIG. 3 illustrates a high-level workflow diagram for machine-learning interatomic potentials of a given atomic system, according to some embodiments.

FIG. 4 illustrates an extension of the high-level workflow diagram introduced in FIG. 3, wherein backpropagation is used to determine related forces of the given atomic system, according to some embodiments.

FIG. 5A illustrates a workflow diagram for an autoencoder-assisted energy determination within the context of machine-learning interatomic potentials of an atomic system, according to some embodiments.

FIG. 5B further illustrates the workflow diagram introduced in FIG. 5A, wherein benefits of applying an autoencoder are additionally detailed, according to some embodiments.

FIG. 6 illustrates another workflow diagram for an autoencoder-assisted energy determination within the context of machine-learning interatomic potentials of an atomic system, according to some embodiments.

FIG. 7 illustrates an example implementation of applying an autoencoder-assisted energy determination to a scenario of dissolving salt into water, according to some embodiments.

FIG. 8 is a flow diagram that illustrates a process of executing an autoencoder to learn an auxiliary property of an atomic system, and applying the learned auxiliary property to determine long and short range effects of the atomic system, according to some embodiments.

FIG. 9 is a flow diagram that illustrates an iterative, molecular-dynamics-based processing, according to some embodiments.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative bases for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical application. Various combinations and modifications of the features consistent with the teachings of this disclosure, however, could be desired for particular applications or implementations.

“A”, “an”, and “the” as used herein refers to both singular and plural referents unless the context clearly dictates otherwise. By way of example, “a processor” programmed to perform various functions refers to one processor programmed to perform each and every function, or more than one processor collectively programmed to perform each of the various functions.

Applications of machine-learned interatomic potentials (MLIP) are vast and diversified. However, until the development of the present disclosure, past implementations of MLIP compromised either (1) the ability to scale while including interactions beyond a restricted number of neighbor atoms, (2) the ability to learn long-range effects, and/or (3) the ability to account for discontinuities and/or transitions. When using MLIP to compute energy and forces, it is important to have the flexibility to incorporate all three of those abilities, depending upon a given type of atomic system, and for a more complete and comprehensive analysis. The following few paragraphs detail the context for each of these challenges that were faced by past implementations of MLIP, following by an explanation of how the present disclosure overcomes the need to prioritize one of these effects to the detriment of one or more of the other effects.

In terms of the ability to scale beyond a restricted number of neighbor atoms, past implementations of MLIP were unable to overcome the difficulty of scaling deep learning networks, especially for very large atomic systems. In the past, deep neural networks would take a cutoff of neighbor atoms r_{c}, where information in the deep neural network would then be passed only between atoms within the fixed cutoff distance. Even further limiting was that the common message-passing deep neural networks, such as Nequip, applied this cutoff distance at each level of the deep neural network, such that a given deep neural network with N layers has an effective cutoff of N r_{c} and a number of effective neighboring atoms that scales as (N r_{c})³. This (N r_{c})³ type scaling makes it nearly impossible to partition the atoms in a given atomic system across different processors during a given production run, as is typically of interest to do with large-scale simulation techniques such as molecular dynamics. In addition, the (N r_{c})³ type scaling is computationally cubically expensive, as the number of atoms increases with the cube of N. This lack of ability to scale was still not resolved, even with techniques such as Allegro, which partitions the energy into a per-atom energy

$${E}_{i} = {\sum }_{j ∈ {N}_{i}} {E}_{ij} ( {N}_{i} ) ,$$

wherein Nᵢ is the set of all atoms in the neighborhood of i (i.e. within the cutoff), and no others, and wherein Eᵢⱼ is an effective pairwise energy corresponding to two atoms i and j.

In terms of the ability to learn long-range effects, such as electrostatics and delocalized electrons (e.g., magnetic conductors), past implementations of MLIP, again such as Allegro which is limited to purely local energies, were unable to overcome this difficulty. Energies and forces associated with long-range effects may be strongly affected by longer-range interactions within an atomic system than what can be captured within a reasonable cutoff radius r_{c}, which is typically several Angstroms. This led to either enormously increasing the value of r_{c}, which in turn then leads to increasing instabilities, computation time, and/or memory requirements, or to have long-range effects to be neglected completely, which in turn then leads to a significant loss in accuracy of the given simulation. By focusing on interactions within a neighborhood of some central atom i, the analysis of long-range interaction (e.g., the interaction between central atom i and another atom beyond the cutoff radius r_{c}) is lost.

Even when using an auxiliary network to learn electrostatic point charges using density functional theory (DFT) datasets, which can then be input into a well-known method for computing long-range electrostatic forces and energies (e.g., an Ewald summation), there previously lacked a comprehensive method for incorporating both short-range and long-range effects into a given type of simulation. Other attempts included fitting point charges to DFT-based charges, such as by using Hirshfeld or Mulliken charge partitioning schemes, or deriving effective charge values from other quantities, such as fitting only to the total energy while not accounting for local energies.

None of such attempts addressed the problem of enabling the ability to scale while also enabling the ability to stably incorporate long-range effects. In particular, a serious drawback of such previous methods in the prior art is that atomic charges can fluctuate often and considerably, and therefore the entire potential energy surface may be extremely sensitive to the initial configuration of the simulation, as well as to small perturbations in the atomic positions over the course of the simulation. Moreover, overall charge neutrality must be enforced at all times, e.g.,

$${\sum }_{i} {q}_{i} = {Q}_{total} ,$$

where Qₜₒₜₐₗ is the total charge of the atomic system and sums to 0. Enforcing the neutrality constraint means that the charge update cannot be done locally, without considering all atoms in the atomic system. Put together, the sensitivity of the charge values to precise atomic configurations and the need to enforce charge neutrality made it previously impossible to partition the atomic system into purely-local components and efficiently proceed with the molecular dynamics simulation.

In terms of the ability to account for discontinuities and/or transitions, previous applications of MLIP did not effectively capture discontinuities in the potential energy surface. Often there are segments of the potential energy surface that are smooth with respect to atomic position, and other segments that correspond to a transition (e.g. a magnetic transition, a bond breaking, charge transfer) where there should be an abrupt change in the potential energy surface. Past applications of MLIP failed to target a transition that would make the potential energy surface discontinuous, while also allowing for the potential energy surface to be continuously differentiable and reasonably smooth (and therefore stable) in each region, due to the abrupt change of the given transition.

In order to address these challenges, the present disclosure uses an autoencoder with a restricted latent space in order to learn one or more auxiliary properties of an atomic system, according to some embodiments. By fixing the latent space based on a hyperparameter or some other dimension-based scheme that allows the autoencoder to map the atomic positions and species of an atomic system, the resulting learned auxiliary property is defined by a finite number of discrete states (e.g., charge states, oxidation states, magnetic states, or some other atomic property), which can be used to construct an auxiliary Hamiltonian that is analytical and therefore easily scalable to longer ranges than a conventional MLIP method. In parallel, the atomic positions and species of the atomic system may also be used as input to a machine learning model, such as a deep neural network, in order to learn local energies. The combination of both the auxiliary Hamiltonian description and the learned local energies allows the particular MLIP architectures described herein to determine a total energy of a given atomic system with high precision and while addressing the three challenges previously faced by the scientific community that are described above.

Specifically, the present disclosure provides a scalable solution, given that the autoencoder ensures that the mapping produces a finite, discretized set of states, while still being configured to benefit from the application of large-scale models, such as a deep neural network. Moreover, both long-range and short-range effects are properly accounted for using the combined architecture of an autoencoder and a machine learning model. In addition, discontinuities and/or transitions are more precisely described using the present disclosure, as the discretized set of states allow for abrupt changes to the auxiliary property that is learned by the autoencoder, such that the methods and systems described herein better simulate the breaking of a bond, or a magnetic phase transition to a spin glass, etc.

The following description continues with a general introduction to machine learning techniques that are relevant to the methods for machine-learning interatomic potentials described herein. Next, various embodiments of autoencoder and machine learning model based architectures are discussed. The present disclosure then demonstrates the versatility of the methods and systems described herein for use in determining macro and micro-level properties of various molecular compositions and in implementation into larger-scale simulations, such as molecular dynamics (MD).

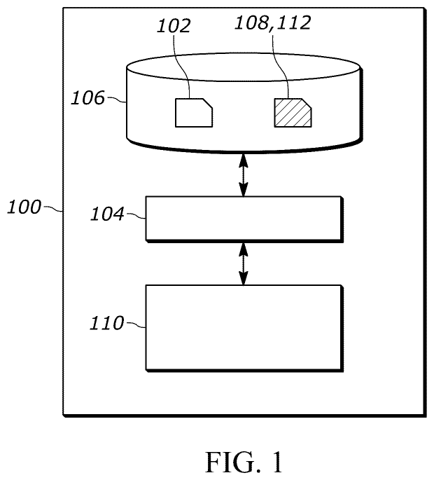

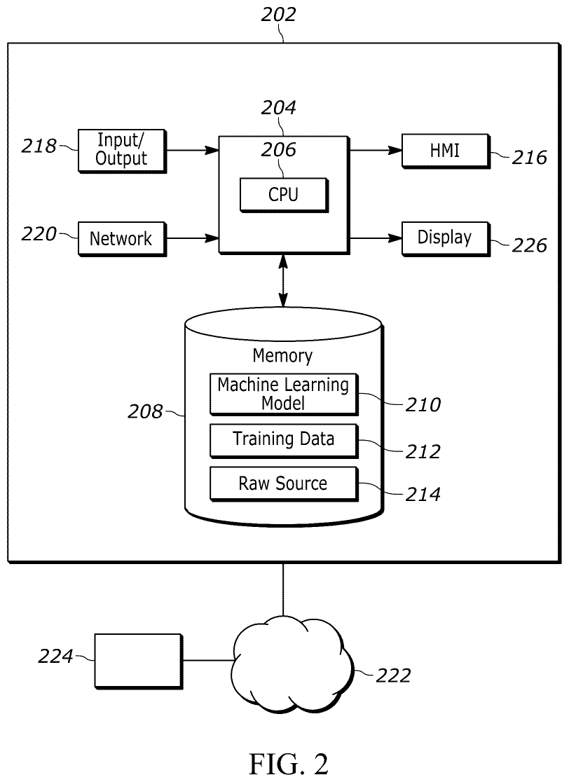

FIG. 1 illustrates a system 100 for training and utilizing a neural network, such as a deep neural network. It should be understood that, while the example embodiments given in the following paragraphs herein with regard to FIGS. 1 and 2 refer to a deep neural network, additional embodiments of FIGS. 1 and 2 may be applied to any other type of neural-network-based or non-neural-network-based machine learning model (e.g., Gaussian processes) that is configured to be developed, trained, and optimized for various machine-learned interatomic potentials applications.

Moreover, and as related to the description herein, a “deep” learning model, such as a deep neural network, may be defined as having multiple hidden layers (e.g., one, two, or tens of hidden layers) in between an input layer and an output layer of the model. A deep learning model may additionally be used to describe a machine learning model that is configured to learn complex patterns and representations based on training and/or validation datasets that are used as inputs to the deep learning model. Additional embodiments pertaining to such types of machine learning models are described herein with regard to machine learning model 210, network 306, deep neural network 406, network 518, learning 618, and block 810.

In some embodiments, the system 100 may comprise an input interface for accessing training data 102 for the neural network. For example, as illustrated in FIG. 1, the input interface may be constituted by a data storage interface 104 which may access the training data 102 from a data storage 106. For example, the data storage interface 104 may be a memory interface or a persistent storage interface, e.g., a hard disk or an SSD interface, but also a personal, local or wide area network interface such as a Bluetooth, ZigBee or Wi-Fi interface or an Ethernet or fiber optic interface. The data storage 106 may be an internal data storage of the system 100, such as a hard drive or SSD, but also an external data storage, e.g., a network-accessible data storage.

In some embodiments, the data storage 106 may further comprise a data representation 108 of an untrained version of the model (e.g., a version of the machine learning model that has yet to be trained) which may be accessed by the system 100 from the data storage 106. It will be appreciated, however, that the training data 102 and the data representation 108 of the untrained neural network may also each be accessed from a different data storage, e.g., via a different subsystem of the data storage interface 104. Each subsystem may be of a type as is described above for the data storage interface 104. In other embodiments, the data representation 108 of the untrained neural network may be internally generated by the system 100 on the basis of design parameters for the neural network, and therefore may not explicitly be stored on the data storage 106. The system 100 may further comprise a processor subsystem 110 which may be configured to, during operation of the system 100, provide an iterative function as a substitute for a stack of layers of the neural network to be trained. Here, respective layers of the stack of layers being substituted may have mutually shared weights and may receive, as input, an output of a previous layer, or for a first layer of the stack of layers, an initial activation, and a part of the input of the stack of layers. The processor subsystem 110 may be further configured to iteratively train the neural network using the training data 102 (e.g., thus generating updated versions of the machine learning model with respect to a first “untrained” version of the model). Here, an iteration of the training by the processor subsystem 110 may comprise a forward propagation part and a backward propagation part. The processor subsystem 110 may be configured to perform the forward propagation part by, amongst other operations defining the forward propagation part which may be performed, determining an equilibrium point of the iterative function at which the iterative function converges to a fixed point, wherein determining the equilibrium point comprises using a numerical root-finding algorithm to find a root solution for the iterative function minus its input, and by providing the equilibrium point as a substitute for an output of the stack of layers in the neural network. The system 100 may further comprise an output interface for outputting a data representation 112 of the trained neural network, this data may also be referred to as trained model data 112. For example, as also illustrated in FIG. 1, the output interface may be constituted by the data storage interface 104, with said interface being in these embodiments an input/output (“IO”) interface, via which the trained model data 112 may be stored in the data storage 106. For example, the data representation 108 defining the ‘untrained’ neural network may during or after the training be replaced, at least in part by the data representation 112 of the trained neural network, in that the parameters of the neural network, such as weights, hyperparameters, and other types of parameters of neural networks, may be adapted to reflect the training on the training data 102. This is also illustrated in FIG. 1 by the reference numerals 108 and 112 referring to the same data record on the data storage 106. In other embodiments, the data representation 112 may be stored separately from the data representation 108 defining the ‘untrained’ neural network. In some embodiments, the output interface may be separate from the data storage interface 104, but may in general be of a type as described above for the data storage interface 104.

FIG. 2 illustrates a computer-implemented method for training and utilizing a neural network, according to some embodiments. The system 200 may include at least one computing system 202. The computing system 202 may include at least one processor 204 that is operatively connected to a memory unit 208. The processor 204 may include one or more integrated circuits that implement the functionality of a central processing unit (CPU) 206 and, in some embodiments, a graphics processing unit (GPU). The CPU 206 may be a commercially available processing unit that implements an instruction set such as one of the x86, ARM, Power, or MIPS instruction set families. During operation, the CPU 206 may execute stored program instructions that are retrieved from the memory unit 208. The stored program instructions may include software that controls operation of the CPU 206 to perform the operation described herein. In some examples, the processor 204 may be a system on a chip (SoC) that integrates functionality of the CPU 206, the memory unit 208, a network interface, and input/output interfaces into a single integrated device. The computing system 202 may implement an operating system for managing various aspects of the operation.

The memory unit 208 may include volatile memory and non-volatile memory for storing instructions and data. The non-volatile memory may include solid-state memories, such as NAND flash memory, magnetic and optical storage media, or any other suitable data storage device that retains data when the computing system 202 is deactivated or loses electrical power. The volatile memory may include static and dynamic random-access memory (RAM) that stores program instructions and data. For example, the memory unit 208 may store a machine learning model 210 or algorithm, a training dataset 212 for the machine learning model 210 (e.g., density functional theory (DFT) training datasets), raw source dataset 214, an autoencoder, etc.

The computing system 202 may include a network interface device 220 that is configured to provide communication with external systems and devices. For example, the network interface device 220 may include a wired and/or wireless Ethernet interface as defined by Institute of Electrical and Electronics Engineers (IEEE) 802.11 family of standards. The network interface device 220 may include a cellular communication interface for communicating with a cellular network (e.g., 3G, 4G, 5G). The network interface device 220 may be further configured to provide a communication interface to an external network 222 or cloud.

The external network 222 may be referred to as the world-wide web or the Internet. The external network 222 may establish a standard communication protocol between computing devices. The external network 222 may allow information and data to be easily exchanged between computing devices and networks. One or more servers 224 may be in communication with the external network 222.

The computing system 202 may include an input/output (I/O) interface 218 that may be configured to provide digital and/or analog inputs and outputs. The I/O interface 218 may include additional serial interfaces for communicating with external devices (e.g., Universal Serial Bus (USB) interface).

The computing system 202 may include a human-machine interface (HMI) device 216 that may include any device that enables the system 200 to receive control input. Examples of input devices may include human interface inputs such as keyboards, mice, touchscreens, voice input devices, and other similar devices. The computing system 202 may include a display device 226. The computing system 202 may include hardware and software for outputting graphics and text information to the display device 226. The display device 226 may include an electronic display screen, projector, printer or other suitable device for displaying information to a user or operator. The computing system 202 may be further configured to allow interaction with remote HMI and remote display devices via the network interface device 220.

The system 200 may be implemented using one or multiple computing systems. While the example depicts a single computing system 202 that implements all of the described features, it is intended that various features and functions may be separated and implemented by multiple computing units in communication with one another. The particular system architecture selected may depend on a variety of factors.

The system 200 may implement a machine learning algorithm 210 that is configured to analyze the raw source dataset 214. The raw source dataset 214 may include raw or unprocessed sensor data that may be representative of an input dataset for a machine learning system. The raw source dataset 214 may include DFT training datasets and/or any other atomic descriptions relating to atomic positions and atomic species of various systems. In some examples, the machine learning algorithm 210 may be a neural network algorithm that is designed to perform a predetermined function. For example, the neural network algorithm may be configured within a context of machine-learning interatomic potentials to learn local energies of a system.

The computer system 200 may store a training dataset 212 for the machine learning algorithm 210. The training dataset 212 may represent a set of previously constructed data for training the machine learning algorithm 210. The training dataset 212 may be used by the machine learning algorithm 210 to learn weighting factors associated with a neural network algorithm. The training dataset 212 may include a set of source data that has corresponding outcomes or results that the machine learning algorithm 210 tries to duplicate via the learning process. In a context of machine-learning interatomic potentials, machine learning algorithm 210 may predict energies and/or other atomic properties of a given atomic system.

The machine learning algorithm 210 may be operated in a learning mode using the training dataset 212 as input. The machine learning algorithm 210 may be executed over a number of iterations using the data from the training dataset 212. With each iteration, the machine learning algorithm 210 may update internal weighting factors based on the achieved results. For example, the machine learning algorithm 210 can compare output results (e.g., annotations) with those included in the training dataset 212. Since the training dataset 212 includes the expected results, the machine learning algorithm 210 can determine when performance is acceptable. After the machine learning algorithm 210 achieves a predetermined performance level (e.g., 100% agreement with the outcomes associated with the training dataset 212), the machine learning algorithm 210 may be executed using data that is not in the training dataset 212. The trained machine learning algorithm 210 may be applied to new datasets to generate annotated data.

The machine learning algorithm 210 may be configured to identify a particular feature in the raw source data 214. The raw source data 214 may include a plurality of instances or input dataset for which annotation results are desired. The machine learning algorithm 210 may be programmed to process the raw source data 214 to identify the presence of the particular features. The machine learning algorithm 210 may be configured to identify a feature in the raw source data 214 as a predetermined feature (e.g., an atomic system comprising water molecules has evidence of hydrogen and oxygen). The raw source data 214 may be derived from a variety of sources. For example, the raw source data 214 may be actual input data collected by a machine learning system. The raw source data 214 may be machine generated for testing the system. As an example, the raw source data 214 may include DFT training datasets related to different concentrations of salt that has been dissolved into water.

In the example, the machine learning algorithm 210 may then process raw source data 214 and output an indication of predicted local energies. A machine learning algorithm 210 may generate a confidence level or factor for each output generated. For example, a confidence value that exceeds a predetermined high-confidence threshold may indicate that the machine learning algorithm 210 is confident that the identified feature corresponds to the particular feature. A confidence value that is less than a low-confidence threshold may indicate that the machine learning algorithm 210 has some uncertainty that the particular feature is present.

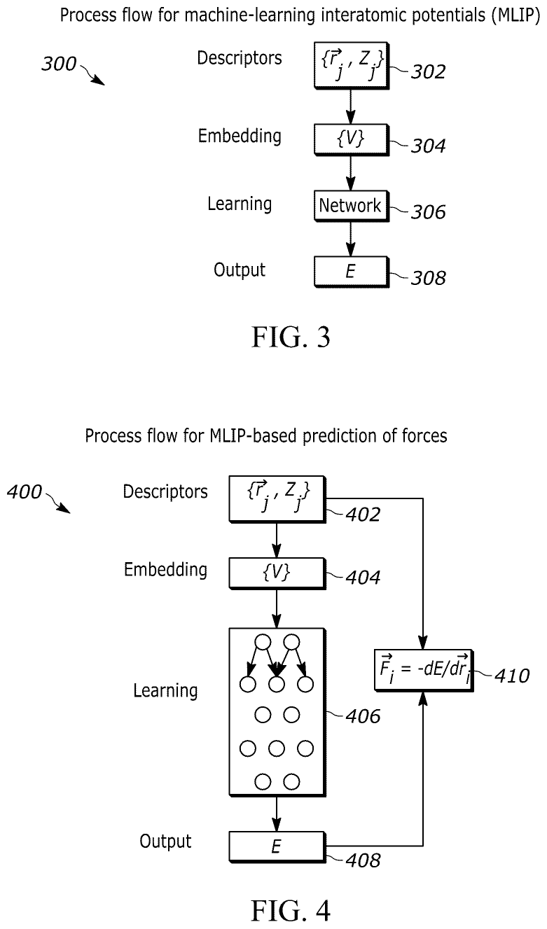

FIG. 3 illustrates a high-level workflow diagram for MLIP of a given atomic system, according to some embodiments.

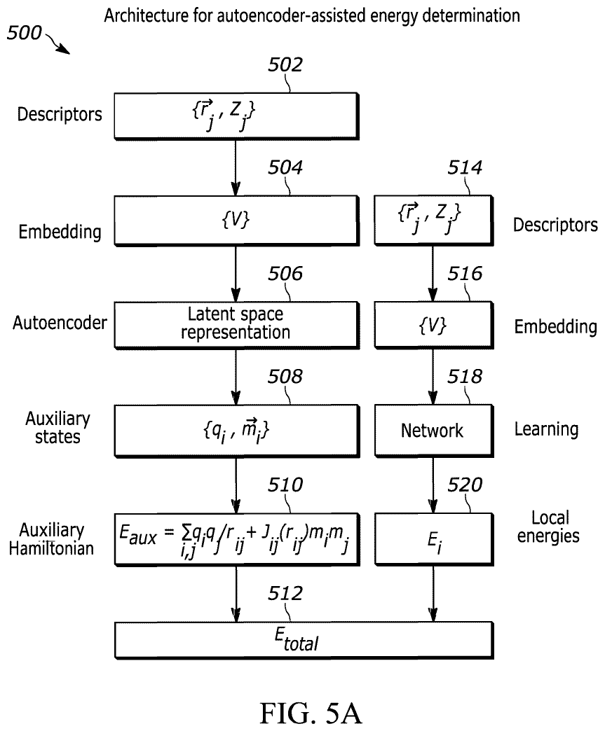

In some embodiments, MLIP, as used and described herein, may be used to map a set of atomic positions, {\vec{r}ᵢ}, and corresponding atomic species, {Zᵢ}, of a given atomic system to a scalar energy, E, as shown in FIG. 3, and, by extension, to additional properties such as forces {\vec{F}ᵢ}, as shown in FIG. 4. In some embodiments, this may be considered to be an equivalent to learning the potential energy surface of the atomic system.

As applied herein, atomic species may refer to atomic number, isotope, an elemental description, or any other property that is used to distinguish different atomic identities over the simulation.

As shown in process 300, atomic positions and atomic species may be referred to as atomic descriptors 302, or to an atomic description 302. For example, in some embodiments in which process 300 resembles a process flow that is being fulfilled for a customer, the customer may provide a request to determine the total energy of a given atomic system, and then provide an atomic description 302 to the computing system that is operating the method shown in FIG. 3. It should similarly be understood that the atomic positions and atomic species within atomic descriptors 302 refers to data that, when compiled, provides a simulated atomic structure of the atomic system, based on the provided atomic positions and atomic species.

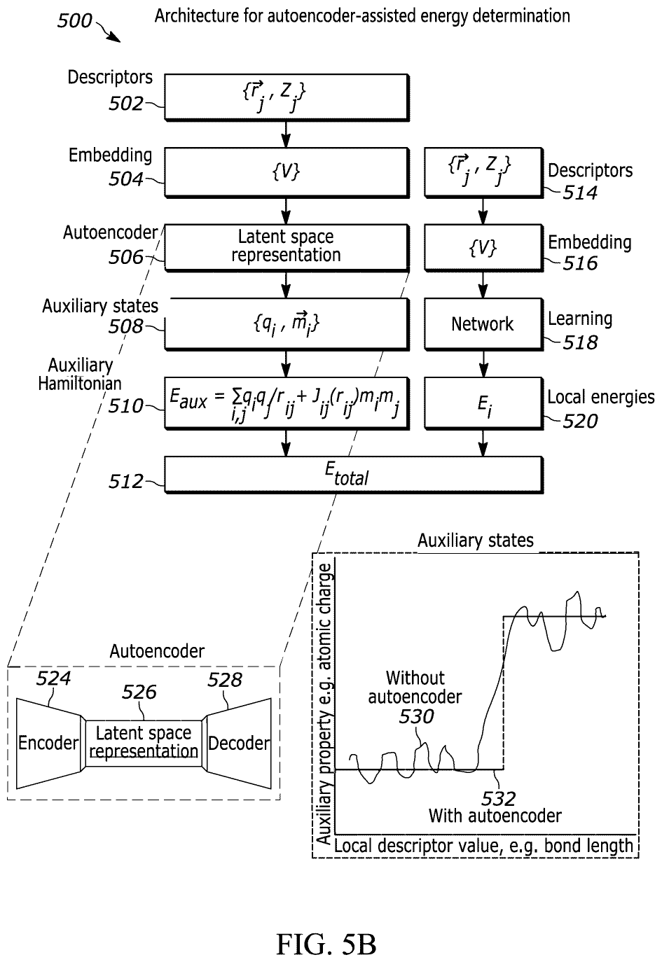

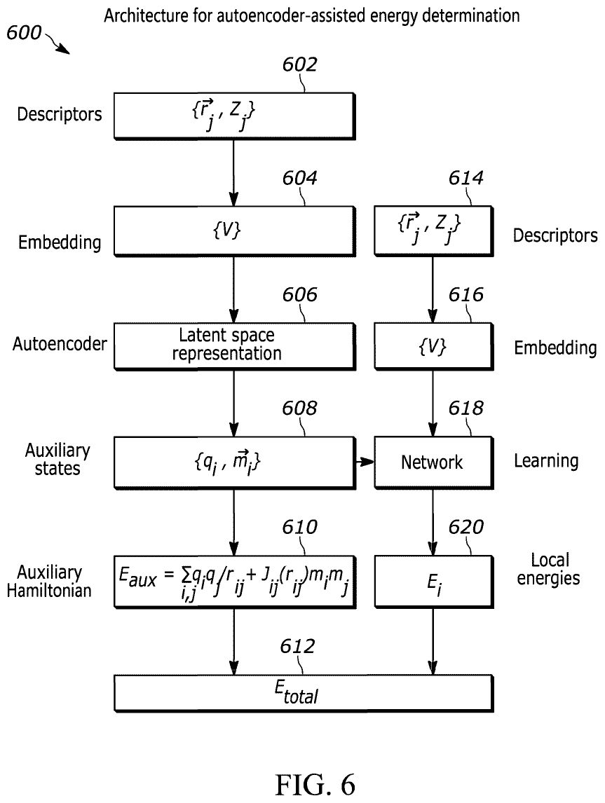

Embedding 304 refers to the conversion of the atomic positions and species into inputs for the interatomic potentials, which are denoted as {V} in the figure. These inputs for the interatomic potentials are also referred to herein as atomic descriptors. The embeddings may be designed to be invariant or covariant with respect to certain symmetry groups of the atomic system or of physics, such as translation, rotation, exchange of atoms, or various crystal symmetries. Such an embedding is additionally discussed with regard to FIGS. 5A, 5B, and 6 herein. Embedding 304 is then provided as an input to “network” 306, wherein the learning of one or more properties about the atomic system takes place. FIGS. 3 and 4 are designed to demonstrate an overall process flow of MLIP, while FIGS. 5A, 5B, and 6 will illustrate the combined use of an autoencoder and a machine learning model during the learning 306 stage.

The one or more properties learned during the learning 306 stage are then used to calculate a total energy of the atomic system, which is also referred to as output 308 in FIG. 3.

Process 300 may be applied to various computational simulations, such as those that reconstruct structures from experimental data, molecular dynamics simulations, methods for finding a particular atomic configuration for an atomic system, atomic Monte Carlo or grand canonical Monte Carlo simulations, and even for simulations that identify likely reactions and/or transition states.

FIG. 4 illustrates an extension of the high-level workflow diagram introduced in FIG. 3, wherein backpropagation is used to determine related forces of the given atomic system, according to some embodiments.

Similarly to that which was introduced in FIG. 3, process 400 depicts a set of atomic positions and atomic species that are embedded into atomic descriptors during the embedding 404 stage. Then, one or more machine learning models are applied during learning 406 stage in order to determine the total energy of an atomic system, as shown by output 408.

As additionally illustrated in FIG. 4, learning 406 refers to a deep neural network. A deep neural network typically has several layers that are learned using backpropagation, wherein the weights of the network are optimized to minimize a loss function such as L=|E_{pred}−E_{actual}|², and wherein E_{actual} are the training data extracted from a higher-fidelity method, such as DFT. Backpropagation may also be referred to as backpropagation through the network model, wherein weights of the network are adjusted based on the model's error rate. An example of a technique that applies backpropagation is pytorch's autograd functionality.

In some embodiments, backpropagation may also be used to predict forces, denoted as forces 410 in FIG. 4, as the derivative of the total energy with respect to atomic positions. The deep neural network may then also be further trained on forces using a loss function such as

$$L = {\sum }_{i} {\vert {\vec{F}}_{i , pred} - {\vec{F}}_{i , actual} \vert}^{2} ,$$

and again using high-fidelity forces, such as that of DFT. The loss function may also focus on the stress tensor, or a combination of two or more of the above, according to some embodiments.

Particular embodiments illustrated in FIG. 4 refer to learning 406 as being implemented using a deep neural network (e.g., Nequip, Allegro) in order to determine both a total energy and forces using backpropagation. However, other embodiments of process 400 may refer to learning 406 as being implemented using one or more Gaussian processes (e.g., FLARE). As utilized herein, one or more Gaussian processes may refer to the use of one or more of such processes that, when combined, implement a model. The model may then be referred to as a Gaussian process model, or a Gaussian-based model.

Depending upon a particular implementation of process 300 and 400 for a given problem statement provided by a customer, it should be understood that learning 306 and 406 may be customized to refer to a deep neural network or to one or more Gaussian processes. Furthermore, Gaussian processes and deep neural networks may be defined as the two main classes of MLIP. Thus, workflow diagrams illustrated in all figures and their corresponding text herein are meant to refer to MLIP implementations that include those that are using either Gaussian processes or deep neural networks, depending up the given implementation of the present disclosure.

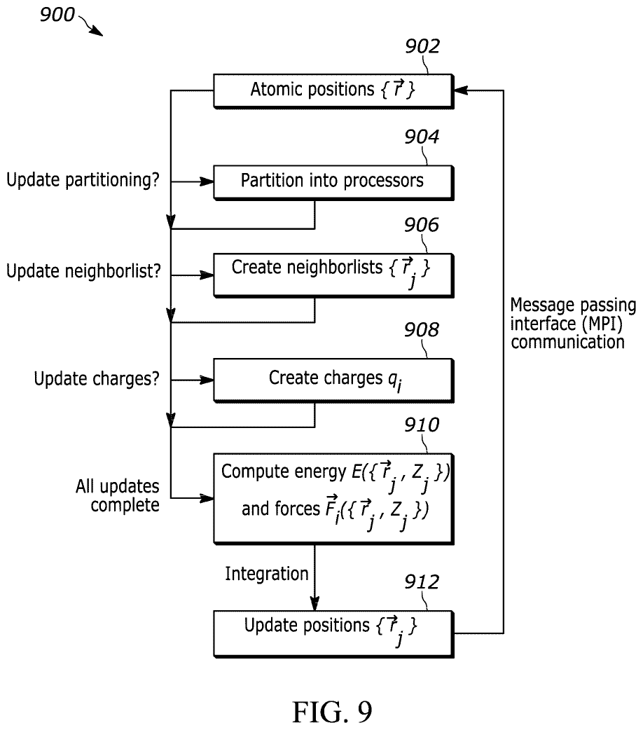

Moreover, an example embodiment of a molecular dynamics algorithm using the type of approach depicted in FIG. 4 is additionally illustrated in FIG. 9.

FIGS. 5A and 5B illustrate a workflow diagram for an autoencoder-assisted energy determination within the context of machine-learning interatomic potentials of an atomic system, according to some embodiments.

As introduced above, and in order to ensure that the one or more models encompassed within learning 306 or learning 406 are configured to capture significant topology and/or charge transitions while also eliminating spurious noise when no such transition is occurring, learning 306 or learning 406 may resemble a combination of an autoencoder 506 and learning network 518. As introduced above, learning network 518 may resemble a deep neural network or one or more Gaussian processes that are configured to be combined into a Gaussian-based model.

Moreover, autoencoder 506 may be defined as having a latent space of restricted dimension, such that it may then be configured to learn atomic-system-specific transitions.

In some embodiments, autoencoder 506 may resemble a pytorch module with parameters that are learned during a training stage. The parameters may then be fixed, and used to predict one or more auxiliary properties 508, such as charge, during a given iteration of process 500.

Autoencoder may also be defined as an autoencoder of restricted latent space of dimension D, which is referred to as latent space representation in FIG. 5A. The value of D may correspond to the number of expected states, or it may be a hyperparameter that is selected during a training stage. Moreover, the determination of dimension D may be further influenced by the complexity of the given atomic system or by the type of auxiliary property being learned.

In some embodiments, autoencoder 506 may resemble a variational autoencoder, a regularized autoencoder, a sparse autoencoder, or any other type of artificial neural network that maps the atomic descriptors 502 through a restricted-dimension latent space 506 to predict an auxiliary property 508.

As shown in FIG. 5A, the output of autoencoder 506 is a learned auxiliary property that is defined by a finite set of discrete states. This is also referred to as auxiliary states 508 in the figure. The discretized set of states is equal to the number of the chosen dimension of the latent space of autoencoder 506. In some embodiments, this may also be referred to as the dimension of the hyperparameter. For example, the learned auxiliary property 508 may refer to atomic charges, wherein the atomic charges only change when a substantial transformation of the local environment in which the atomic system is being simulated is detected.

In some embodiments, auxiliary property 508 may be one or more charge states ({qᵢ}), oxidation states, magnetic states ({\vec{m}ᵢ}), or some other atomic property that is specifically relevant to the given atomic system being studied. In addition, there may be a transformation within the decoder 528 between the restricted latent space and the floating-point-valued physical property (charge state, oxidation state, magnetic state, etc.) of the auxiliary Hamiltonian.

The one or more auxiliary properties are then used to determine an auxiliary Hamiltonian description of the atomic system. As shown in the figure, the auxiliary Hamiltonian description encompasses the analysis of both short-range and long-range effects, while also taking into account discontinuities and/or transitions as pertaining to the given atomic system. An example of such a transition is illustrated in FIG. 5B and is additionally discussed below. Moreover, the illustrated embodiments in FIG. 5A depict an auxiliary Hamiltonian that describes energies of the atomic system. However, other embodiments of FIG. 5A may depict an auxiliary Hamiltonian that describes forces of the atomic system.

In parallel, embedded atomic descriptors are also provided to learning 518, as indicated by atomic descriptors 514 and embedding 516. It should be understood that in embodiments depicted in FIG. 5A, the sequence illustrated by 502, 504, 506, 508, and 510 may happen in parallel with the sequence illustrated by 514, 516, 518, and 520, or in a sequential ordering. Embodiments illustrated in FIG. 6 also demonstrate a sequential ordering of process 600 and is additionally discussed below.

As introduced above, learning 518 may resemble some form of deep neural network or Gaussian-based model that is configured for machine-learning interatomic potentials and for learning local energies 520 of an atomic system. Following the examples given above, if and when a target property that is being learned is related to energy, then auxiliary Hamiltonian 510 may describe energies of the atomic system and learning 518 may be configured to learn local energies, such that a total energy 512 may be determined for the atomic system. If, in other embodiments, the target property that is being learned is related directly to forces, then auxiliary Hamiltonian 510 may describe forces of the atomic system and learning 518 may be configured to directly learn forces, such that a total related forces 512 may be determined for the atomic system.

Following the learning of both the auxiliary Hamiltonian description and the local energies of the atomic system, the total energy of the atomic system may then be determined. In some embodiments, the total energy determination is based on the strictly local energies that were learned in learning 518, and on the analytical, auxiliary Hamiltonian description 510 that was determined via autoencoder 506. This ensures that the total energy determination accounts for long-range effects. In some embodiments, the auxiliary Hamiltonian description may resemble an Ewald summation of per-atom charges, or a magnetic Hamiltonian description that includes learned parameters J(rᵢⱼ).

Referring back to atomic descriptors 502 and 514, they are specifically local atomic descriptors in that it is an analysis of atoms j in the neighborhood of a central atom i. Thus, learning 518, if executed using an MLIP-based model such as Allegro, outputs local energies

$${E}_{i} = {\sum }_{j ∈ {N}_{i}} {E}_{ij} .$$

Another element that is relevant to architectures shown in 500 and 600 is configuring and accounting for charge neutrality. For example, autoencoder 506 may be configured to force charge neutrality when executing. When the autoencoder receives an indication that charge neutrality should be obeyed, the auxiliary property is learned while also conforming to charge neutrality.

In some embodiments, and for electrostatic applications, the loss function of the autoencoder could be generalized to include charge neutrality for the auxiliary states in the latent space, on top of the usual loss. This constrains the autoencoder to learn a latent space as a function of input coordinates and atom types that respects the total charge of the atomic system (e.g., usually zero).

During the dynamics, there may be an additional step pertaining to charge neutrality in order to ensure

$${\sum }_{i} {q}_{i} = {Q}_{total} .$$

However, rather than having highly fluctuating charges and therefore the need for frequent re-evaluation of global neutrality, the present disclosure is configured to retain charges as approximately constant in most steps, due to the finite number of discrete states, and thus a correspondingly small number of possibilities for change. In addition, the computing system is configured to deduce when the auxiliary states have changed as a function of the input coordinates and species (e.g., via a list of auxiliary variables and a product of the autoencoder), thus allowing for re-computation during the dynamics only when strictly needed. This is analogous to how, in modern scalable dynamics (e.g. LAMMPS), the atom neighbor list is not computed at every time step. This is illustrated in FIG. 9 as well.

In some embodiments, a customer may include an indication to force charge neutrality, or not to force charge neutrality. In other embodiments, the architectures illustrated in 500 and 600 may be configured to determine if charge neutrality should be obeyed. For example, based on incoming information from the customer indicating that this is a problem pertaining, or not, to electrostatics.

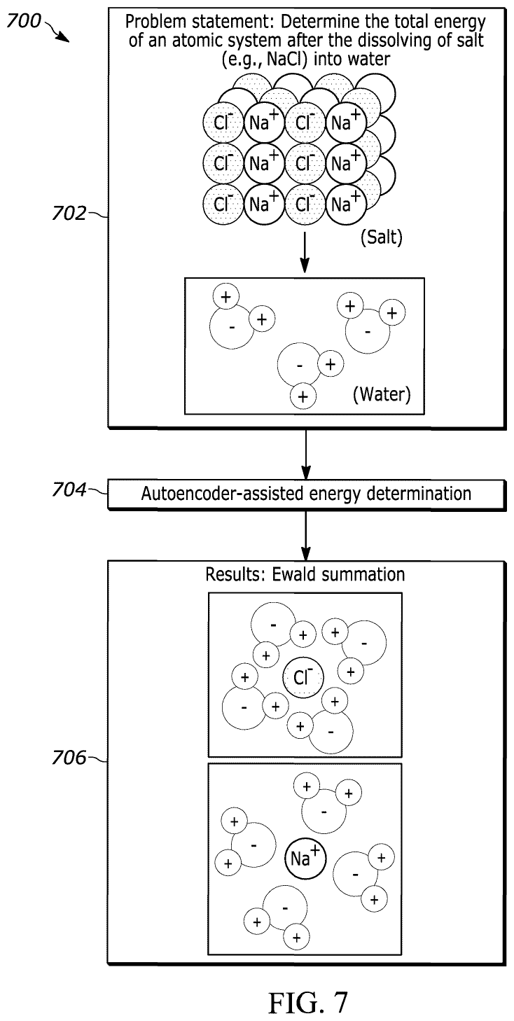

In some scenarios pertaining to certain atomic systems, such as when dealing with solids of liquids, charge neutrality is not forced. However, in a scenario in which salt is dissolved into water (see also description pertaining to FIG. 7 herein), excess charge in the region of study does not correspond to a reasonable interpretation or simulation of salt being dissolved into water, and thus charge neutrality is forced. In yet another example, some scenarios pertaining to point charges would require the autoencoder to conform with charge neutrality, while scenarios pertaining to polarizability or magnetic moment may not require such a constraint.

Forces can be computed as a summation of

$${\vec{F}}_{j , local} = {\sum }_{i} d {E}_{i , local} / d {\vec{r}}_{j}$$

and the auxiliary \vec{F}_{j,aux}=d Eₐᵤₓ/d \vec{r}ⱼ. Because the autoencoder is designed to keep the auxiliary properties approximately constant, this latter derivative can be approximated as an analytical term e.g. for electrostatics Fⱼ≈qᵢqⱼ/rᵢⱼ².

The output of the network can be an energy, forces, stresses, polarizability, point charges, electrostatic field, magnetic moment, and/or any other atomic-system-wide and/or atom-specific property, which can be used in a simulation such as molecular dynamics, a structure or conformation search, a Monte Carlo simulation, or any other atomistic simulation.

As shown in FIG. 5B, autoencoder 506 may resemble that which is illustrated with encoder 524, latent space representation 526, and decoder 528. Latent space representation 526 resembles a lower-dimension space, with respect to the dimensions of encoder 524 and decoder 526, that is configured to map atomic descriptors to one or more auxiliary properties of the given atomic system. Moreover, autoencoder 506 may resemble an artificial neural network or any other feed-forward network that is configured to learn auxiliary properties of atomic systems.

Encoder 524 is used to encode the inputs, which refers to some combination of the atomic positions, and atomic species 502, which have been transformed into some embedding 504 of the given atomic system. Latent space representation 526 then refers to a restricted latent space with a specific dimension D, wherein core features, information, and/or dependencies of the input data are processed and then provided to decoder 528. Decoder 528 is then tasked with generating the auxiliary property based on the core features learned within the restricted latent space.

As also illustrated in FIG. 5B, auxiliary states 508 that have been learned via autoencoder 506 enable for discontinuities and/or transitions within the potential energy surface. In the example shown in FIG. 5B, the vertical dashed line within line 532 illustrates the breaking of a bond, as there is an abrupt change in atomic charge with increasing bond length. Line 530 illustrates the same type of transition without having learned the auxiliary states 508 using autoencoder 506. The abrupt transition is lost and the auxiliary property is much more volatile, leading to instabilities in the multidimensional potential energy surface (PES).

FIG. 6 illustrates another workflow diagram for an autoencoder-assisted energy determination within the context of machine-learning interatomic potentials of an atomic system, according to some embodiments.

Similarly to that which is illustrated by process 500 in FIGS. 5A and 5B, process 600 demonstrates the use of atomic positions and species to determine a total energy of a given atomic system. Atomic descriptors 602 are embedded during embedding 604 as inputs for the interatomic potentials, and subsequently provided to autoencoder 606. As above with process 500, autoencoder 606 is configured to have a latent space representation with a restricted dimension.

As shown in FIG. 6, the output of autoencoder 606 is a learned auxiliary property that is defined by a finite set of discrete states. This is also referred to as auxiliary states 608 in the figure. The discretized set of states is equal to the number of the chosen dimension of the latent space of autoencoder 606. In some embodiments, the discretized set of states within the latent space representation 526 are then further transformed to a set of auxiliary states 608 through a decoder 528.

The one or more auxiliary properties are then used to determine an auxiliary Hamiltonian description of the atomic system. As shown in the figure, the auxiliary Hamiltonian description encompasses the analysis of both short-range and long-range effects, while also taking into account discontinuities and/or transitions as pertaining to the given atomic system.

In parallel, embedded atomic descriptors are also provided to learning 618, as indicated by atomic descriptors 614 and embedding 616. As depicted in FIG. 6, the sequence of 602, 604, 606, and 608 may occur in parallel to the embedding of the atomic description depicted with the sequence of 614 and 616. However, prior to executing the model in learning 618, auxiliary states 608 are also provided as inputs. This may be advantageous in particular embodiments wherein providing the machine learning model with both embedded atomic descriptors and auxiliary states ensures a more robust model for learning local energies.

Similarly to that which is illustrated in FIGS. 5A and 5B, both the determined auxiliary Hamiltonian description 610 and the learned local energies 620 are then used to determine the total energy 612 of the atomic system and may, in some embodiments, be also used to determine forces, stresses, or some other physically meaningful value.

FIG. 7 illustrates an example implementation of applying an autoencoder-assisted energy determination to a scenario of dissolving salt into water, according to some embodiments.

In the given scenario depicted in FIG. 7, process 700 describes an overall process of receiving a request from a customer to determine a property about an atomic system that is supposed to simulate salt being dissolved into water. As shown in block 702, a problem statement, received from the customer in this scenario, requests for the determination of the total energy of a given system in which a certain concentration of NaCl is dissolved into water.

In some embodiments, the customer may additionally provide the atomic positions, as shown by the crystalline lattice of NaCl and the water molecules in block 702 of the figure, and the atomic species, understood to be sodium, chlorine, oxygen, and hydrogen from the problem statement.

In other embodiments, the customer provides merely the request to determine the total energy of the given atomic system, and methods and systems such as those described herein are configured to determine the atomic positions and species.

Subsequently, the atomic description, comprising the atomic positions and species, is provided to a computing system with an architecture such as that which is shown in FIG. 5A, 5B, or 6. Block 704 thus encompasses the embedding of the atomic positions and species into atomic descriptors, the providing of the atomic descriptors to an autoencoder, the learning of a given auxiliary property based on those atomic descriptors, and the determination of a resulting auxiliary Hamiltonian description of the atomic system. Block 704 also encompasses providing the embedded atomic description to a deep neural network or to a Gaussian-based model in order to determine local energies of the given atomic system.

In some embodiments, and as illustrated in FIG. 6, the learned auxiliary properties of the autoencoder may be provided as an input, in addition to the embedded atomic descriptors being provided as input, to the deep neural network or Gaussian-based model.

The auxiliary Hamiltonian description and the learned local energies may then be used to determine the request of the customer, such as the determination of the total energy of the atomic system. As shown in block 706, the contribution from the auxiliary Hamiltonian may be performed via an Ewald summation.

The results of block 706 may then be provided to the customer, according to some embodiments. Block 704 may also encompass two or more iterations of an autoencoder-assisted energy determination, and thus the customer may receive information about results of one or more of those iterations.

The given scenario 700 also demonstrates the versatility of the autoencoder. For example, depending upon the embedding that is completed, the autoencoder may be provided with rotational symmetries and/or exchange symmetries. Then, in a first example, if the restricted-dimension latent space of the autoencoder is fixed to have a dimension of 4, then the autoencoder may be configured to learn that screened charges of sodium ions are always +0.9, that chlorine ions are always −0.9, that the hydrogen of a water molecule has a partial charge of 0.5, and that the oxygen has a partial charge of −1.0.

In a second example, if the restricted-dimension latent space of the autoencoder is fixed to have a dimension of 5, 6, 7, 8, 9, or 10, then the autoencoder may additionally be configured to learn distinctions between water, protons, hydroxyls, and hydronium.

Moreover, the autoencoder is also versatile through the incorporation, or not, of accounting for charge neutrality. For example, if the autoencoder is provided with information indicating that there are 5 sodium ions and 5 chloride ions, and if the dimension of the latent space is fixed at 2, then the autoencoder learns that the total charge prediction is zero.

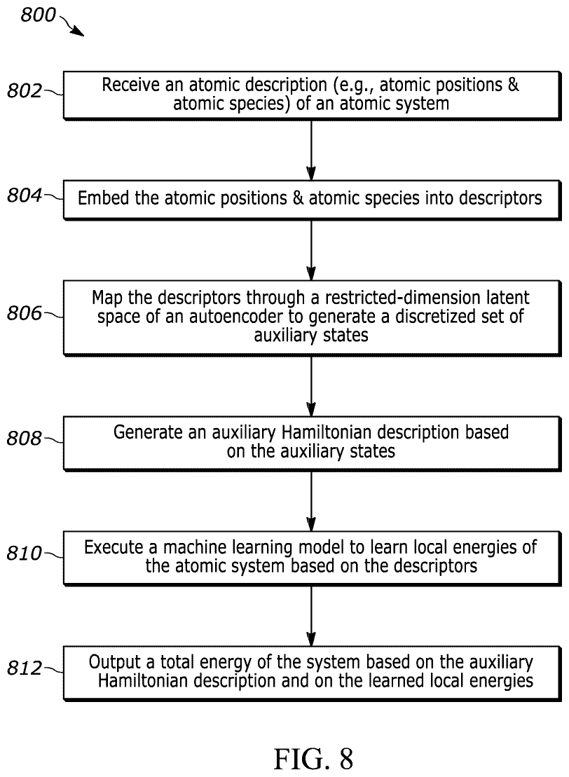

FIG. 8 is a flow diagram that illustrates a process of executing an autoencoder to learn an auxiliary property of an atomic system, and applying the learned auxiliary property to determine long and short range effects of the atomic system, according to some embodiments.

Process 800 is provided within a context of receiving a specific problem statement from a customer and learning specific properties of a given atomic system. In some embodiments, process 800 may occur on one or more processors of a computing system, such as that which is described with respect to FIGS. 1 and 2. A user interface may also be provided via such a computing system, such that one or more customers may submit information regarding requests for MLIP-based simulations that are to be run on the computing system, and receive results of those request.

As shown in block 802, a customer may provide an atomic description of an atomic system, wherein the atomic description includes at least atomic positions and atomic species that are known to exist within the atomic system. The problem statement may further define certain objectives, such as the interest in using machine learning to determine an auxiliary Hamiltonian description of the atomic system, and/or the interest in having a description of the total energy of the atomic system, etc.

In block 804, the atomic positions and species are embedded into atomic descriptors which may be invariant or covariant to certain symmetries of the system. The embeddings are then provided to an autoencoder in block 806, wherein the atomic descriptors are mapped through a restricted-dimension latent space of the autoencoder in order to learn an auxiliary property of the atomic system. The auxiliary property corresponds to a discretized set of states, such as charge states, oxidation states, or magnetic states.

In block 808, the learned auxiliary property is used to generate an auxiliary Hamiltonian description of the given atomic system. Such an auxiliary Hamiltonian description is configured to describe both long-range and short-range effects of the atomic system, due to the use of the atomic positions and species and due to the lack of need to fix an atomic cutoff radius, r_{c}.

In block 810, the embedded atomic descriptors are also provided, either simultaneously or sequentially, to a machine learning model to determine local energies of the atomic system. In some embodiments, the machine learning model may resemble a deep neural network, a Gaussian-based model, or any other MLIP-based model that is configured to learn local energies of an atomic system. Moreover, the learned auxiliary property, described in block 806, may also be provided as an input to the machine learning model, according to some embodiments.

In block 812, a total energy of the atomic system is determined, using the auxiliary Hamiltonian description and the learned local energies.

Following the determination of the total energy of the atomic system, process 800 may be iterated through again. A number of iterations above the initial iteration may be determined based on the specific properties that are intended to be learned by the autoencoder and machine learning model, or based on the complexity of the given problem statement.

Once the total energy has been determined and/or convergence within a given threshold has been met, results of the autoencoder-assisted energy determination are provided to the customer via a customer interface.

In some embodiments, process 800 may resemble a sub-process within a larger context. For example, once an auxiliary Hamiltonian description is determined using process 800, the auxiliary Hamiltonian may then be used as an input to another technique in order to determine a ground state of the atomic system. In another example, once a total energy of the atomic system is determined using process 800, backpropagation may be applied to the autoencoder-assisted energy determination architecture, such as those shown in FIGS. 5A, 5B, and 6, in order to also determine other properties such as related forces of the atomic system. In yet another example, computations of energy and forces, using process 800, may be iteratively incorporated into a molecular dynamics (MD) simulation.

FIG. 9 is a flow diagram that illustrates an iterative, molecular-dynamics-based processing, according to some embodiments. As indicated by the arrow between Update positions 910 and Atomic positions 902, process 900 may be computed more than once. In addition, and as also illustrated by “Update partitioning,” “Update neighbor list,” and “Update charges,” one or more steps within process 900 may be completed during each iteration, during every other iteration, during each N^{th} iteration, etc. The following paragraphs illustrate an example embodiment in which process 900 is being run for the first time.

In block 902, atomic positions {\vec{r}} are enumerated for respective atoms within the given atomic system. As introduced above, a problem statement that has been provided by a customer may include an atomic description, such as information about atomic positions and atomic species within the atomic system of focus for the problem statement.

In block 904, those atomic positions are partitioned into two or more processors, such as two or more of processors 204 that have access to memory 208, which stores the MLIP model. In some embodiments, processors 204 are configured to partition respective atomic positions such that adjacent atoms are partitioned onto the same processor. This may reduce the amount of Message Passing Interface (MPI) communications that need to take place during and/or between iterations of process 900. As shown by the arrows, this partitioning may not need to be repartitioned every timestep of the simulation.

In block 906, an atomic neighbor list is created of the set of all atoms j within the neighborhood of atom i. For example, the neighbor list may include all atoms within a cutoff radius r_{c} from atom i. As introduced above, atomic positions may be defined within atomic descriptors {\vec{r}ⱼ, Zⱼ}, such as in atomic descriptors 502, 514, 602, and 614, for each atom j within the atomic system. As shown by the arrows, this neighbor list may not need to be regenerated every timestep of the simulation.

In block 908, a charge list may be created based on an autoencoder, such as in the architectures described in FIGS. 5A, 5B, and 6. As shown by the arrows, these charges may not need to be regenerated every timestep of the simulation, because they may be relatively stable. In some embodiments, a charge rebalancing step is further performed here to ensure

$${\sum }_{i} {q}_{i} = {Q}_{total} ,$$

wherein Qₜₒₜₐₗ is the assigned total charge of the system.

In block 910, the total energy of the atomic system, E({\vec{r}ⱼ, Zⱼ}), is determined using an autoencoder-assisted energy determination, such as in those architectures described in FIGS. 5A, 5B, and 6 herein. As introduced above, the energy computation provides the atomic positions, species, charges, and/or other properties, and provides them to both an autoencoder and to a machine learning model. The auxiliary Hamiltonian description and local energies are respectively learned, and then applied in order to calculate a total energy of the atomic system. In addition, the forces, \vec{F}ᵢ({\vec{r}ⱼ, Zⱼ}), may also be computed, such as via backpropagation, and using the values of the local energies that have been learned by the neural network 518, or 618.

In block 912, the computed energies and forces are used as input to update the atomic positions, such as by using an integration scheme, like leapfrog integration.

As shown by the arrow between blocks 912 and 902, MPI then communicates results between respective ones of the processors used in the partitioning in order to implement updated atomic positions and/or updated total energy based on that particular iteration of process 900.

As introduced above, process 900 may be iterated through more than once, and blocks 904, 906, 908, and/or 910 may be updated during at least some of the subsequent iterations of process 900. For example, and following the determination of updated atomic positions via blocks 912 and 902, partitioning of the atomic positions onto respective processors may be updated prior to proceeding with creating neighbor lists in block 906. In some embodiments, the partitioning may be updated every N iterations, wherein N may equal a value such as 1000. In another example, and following the partitioning of atomic positions in block 904, the atomic neighbor list in block 906 may be updated. In some embodiments, the neighbor lists may be updated every M iterations, wherein M may equal a value such as 100. In yet another example, and following the creating of the neighbor lists in block 906, charges may be updated. Similarly, charges may or may not be updated each and every iteration, depending upon the integration that was done to update positions 912 during the previous iteration.

It should be understood that process 900 may be repeated any given number of times according to convergence criteria that have been set, time limitations, computing power constraints, or any other number of implementation and/or customer specific criteria.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A computer-implemented method for executing a machine learning network for machine-learned interatomic potentials, comprising:
receiving data indicating an atomic description of an atomic system, wherein the atomic description comprises atomic positions and atomic species of respective atoms in the atomic system;
embedding the data indicating the atomic positions and the atomic species into atomic descriptors;
mapping the embedded atomic descriptors through a restricted-dimension latent space of an autoencoder to learn a discretized set of auxiliary states of the atomic system;
generating an auxiliary Hamiltonian description based on the learned auxiliary states;
providing the embedded atomic descriptors and the learned auxiliary states as inputs to a machine learning model;
executing the machine learning model to learn local energies of the atomic system; and
outputting a total energy of the atomic system based on the auxiliary Hamiltonian description and on the learned local energies.

2. The computer-implemented method of claim 1, further comprising:
determining, based on the outputted total energy of the atomic system, related forces of the atomic system through backpropagation; and
outputting the related forces.

3. The computer-implemented method of claim 2, wherein:
the outputted total energy and the outputted related forces of the atomic system are provided for integration within a given iteration of a molecular dynamics simulation; and
the method further comprises:
receiving an indication that, during a subsequent iteration of the molecular dynamics simulation, one or more of the atomic positions have been updated with respect to the atomic positions within the atomic description;
embedding the updated atomic positions and the atomic species into updated atomic descriptors; and
re-mapping the updated embedded atomic descriptors and re-executing the machine learning model to output an updated total energy of the atomic system.

4. The computer-implemented method of claim 1,
determining, based on a type of auxiliary states that is to be learned, to force charge neutrality of the atomic system during the mapping the embedded atomic descriptors through the restricted-dimension latent space of the autoencoder; and
providing an indication of required charge neutrality to the autoencoder.

5. The computer-implemented method of claim 1,
determining, based on a type of auxiliary states that is to be learned, not to force charge neutrality of the atomic system during the mapping the embedded atomic descriptors through the restricted-dimension latent space of the autoencoder; and
providing an indication of non-restriction of charge neutrality to the autoencoder.

6. The computer-implemented method of claim 1, further comprising:
additionally receiving an indication of a type of auxiliary states that is to be learned; and
determining a dimension for the restricted-dimension latent space that is to be applied based, at least in part, on complexity of the atomic system or of the type of auxiliary states.

7. The computer-implemented method of claim 1, wherein the discretized set of auxiliary states are one or more of:
charge states;
oxidation states; or
magnetic states.

8. The computer-implemented method of claim 1, wherein the autoencoder is a variational autoencoder, a regularized autoencoder, or a sparse autoencoder.

9. The computer-implemented method of claim 1, wherein the machine learning model is a deep neural network or is one or more Gaussian processes.

10. A computer-implemented method for executing a machine learning network for machine-learned interatomic potentials, comprising:
receiving data indicating a request from a customer to determine a total energy of an atomic system, wherein the request comprises atomic positions and atomic species of respective atoms in the atomic system;
embedding the data indicating the atomic positions and the atomic species into atomic descriptors;
mapping the embedded atomic descriptors through a restricted-dimension latent space of an autoencoder to learn a discretized set of auxiliary states of the atomic system;
generating an auxiliary Hamiltonian description based on the learned auxiliary states;
executing a machine learning model to learn local energies of the atomic system based on the embedded atomic descriptors;
outputting the total energy of the atomic system based on the auxiliary Hamiltonian description and on the learned local energies; and
providing the total energy to the customer.

11. The computer-implemented method of claim 10, wherein:
the atomic descriptors are inputs for interatomic potentials that describe the atomic system; and
the atomic descriptors are invariant or covariant with respect to a symmetry group of the atomic system.

12. The computer-implemented method of claim 10, wherein:
providing the learned auxiliary states as an input to the machine learning model; and
executing the machine learning model to learn the local energies of the atomic system, based on the embedded atomic descriptors and on the learned auxiliary states.

13. The computer-implemented method of claim 10, wherein the discretized set of auxiliary states are one or more of:
charge states;
oxidation states; or
magnetic states.

14. The computer-implemented method of claim 10, wherein:
the request further comprises an indication of a type of discretized set of auxiliary states that is to be learned; and
the method further comprises determining a dimension for the restricted-dimension latent space that is to be applied based, at least in part, on complexity of the atomic system or of the type of auxiliary states.

15. The computer-implemented method of claim 14, further comprising:
determining, based on the request, to force charge neutrality of the atomic system during the mapping the embedded atomic descriptors through the restricted-dimension latent space of the autoencoder; and
providing an indication of required charge neutrality to the autoencoder.

16. The computer-implemented method of claim 14, further comprising:
determining, based on the request, not to force charge neutrality of the atomic system during the mapping the embedded atomic descriptors through the restricted-dimension latent space of the autoencoder; and
providing an indication of non-restriction of charge neutrality to the autoencoder.

17. A non-transitory, computer-readable medium storing program instructions that, when executed on or across one or more processors, cause the one or more processors to:
receive data indicating an atomic description of an atomic system, wherein the atomic description comprises atomic positions and atomic species of respective atoms in the atomic system;
embed the data indicating the atomic positions and the atomic species into atomic descriptors;
map the embedded atomic descriptors through a restricted-dimension latent space of an autoencoder to learn a discretized set of auxiliary states of the atomic system;
generate an auxiliary Hamiltonian description based on the learned auxiliary states;
execute a machine learning model to learn a local scalar vector or tensor property of the atomic system based on the embedded atomic descriptors; and
output a total property of the atomic system based on the auxiliary Hamiltonian description and on the learned local scalar vector or tensor property.

18. The non-transitory, computer-readable medium of claim 17, wherein the program instructions further cause the one or more processors to:
provide the learned auxiliary states as an input to the machine learning model; and
execute the machine learning model to learn the local scalar vector or tensor property of the atomic system, based on the embedded atomic descriptors and on the learned auxiliary states.

19. The non-transitory, computer-readable medium of claim 17, wherein the discretized set of auxiliary states are one or more of:
charge states;
oxidation states; or
magnetic states.

20. The non-transitory, computer-readable medium of claim 17, wherein:
the local scalar vector or tensor property is local energies and the total property is total energy; or
the local scalar vector or tensor property is related forces and the total property is total force.
